(19) United States
(12) Patent Application Publication
(10) Pub. No.: US 2024/0107834 A1
(43) Pub. Date: Mar. 28, 2024

(54) DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR)

(73) Assignee: Samsung Display Co., LTD., Yongin-si (KR)

(21) Appl. No.: 18/295,880

(22) Filed: Apr. 5, 2023

(30) Foreign Application Priority Data
Sep. 26, 2022 (KR) 10-2022-0121852

(51) Int. Cl. H10K 59/131

(52) U.S. Cl. CPC H10K 59/131

(57) ABSTRACT

A display device includes a pixel circuit layer including a base layer and a pixel circuit on the base layer; and a light emitting element layer disposed on the pixel circuit layer, the light emitting element layer including a light emitting element. The pixel circuit layer includes a lower auxiliary electrode layer; an active layer; and an interlayer conductive layer. The pixel circuit includes a driving transistor. The lower auxiliary electrode layer forms a first overlapped lower layer and a second overlapped lower layer. The interlayer conductive layer forms a gate electrode of the driving transistor. The first overlapped lower layer overlaps the gate electrode in a plan view. The second overlapped lower layer is electrically disconnected from the first overlapped lower layer.

### CROSS-REFERENCE TO RELATED APPLICATION(S)

This application claims priority to and benefits of Korean patent application No. 10-2022-0121852 under 35 U.S.C. § 119 filed on Sep. 26, 2022 in the Korean Intellectual Property Office, the entire contents of which are incorporated herein by reference.

### BACKGROUND

### 1. Technical Field

The disclosure generally relates to a display device.

### 2. Description of the Related Art

With the development of information technologies, the importance of a display device which is a connection medium between a user and information increases. The display device may include a light emitting element that emits light and a pixel circuit for driving the light emitting element.

Electrical signals for driving the light emitting element may be applied from the pixel circuit designed by two or more electrode patterns. The electrical signals may interfere with each other, and therefore, a risk such as a signal delay may occur. Accordingly, a pixel circuit structure in which the reliability of electrical signals is improved is required so as to provide a high-quality display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device in which the reliability of an electrical signal in the display device is improved.

A display device may include a pixel circuit layer including a base layer and a pixel circuit disposed on the base layer; and a light emitting element layer disposed on the pixel circuit layer, the light emitting element layer including a light emitting element, wherein the pixel circuit layer includes a lower auxiliary electrode layer; an active layer; and an interlayer conductive layer, the pixel circuit includes a driving transistor, the lower auxiliary electrode layer forms a first overlapped lower layer and a second overlapped lower layer, the interlayer conductive layer forms a gate electrode of the driving transistor, the first overlapped lower layer overlaps the gate electrode in a plan view, and the second overlapped lower layer is electrically disconnected from the first overlapped lower layer.

The active layer may form an active connection layer. The first overlapped lower layer may be electrically connected to a source electrode of the driving transistor through the active connection layer.

The driving transistor may supply an anode signal to the light emitting element. The anode signal may be simultaneously applied to the light emitting element and the first overlapped lower layer in case that the light emitting element emits light.

The first overlapped lower layer may be applied with the anode signal without being applied with a gate signal with respect to the driving transistor. The second overlapped lower layer may be applied with the gate signal without being applied with the anode signal.

The pixel circuit may include a storage capacitor. The active connection layer may form an upper electrode of the storage capacitor. The second overlapped lower layer may form a lower electrode of the storage capacitor.

The light emitting element may include a first electrode; a second electrode; and a light emitting layer electrically connected between the first electrode and the second electrode. The active layer may form an anode signal supply layer. The anode signal supply layer may be electrically connected to the first electrode through an anode contact part.

The anode signal supply layer may be integral with the active connection layer.

The interlayer conductive layer may form an anode connection layer electrically connecting the first overlapped lower layer and the active connection layer.

The active connection layer may be closer to the first electrode than the second overlapped lower layer.

The pixel circuit may include a switching transistor. The interlayer conductive layer may form a gate connection layer electrically connecting the switching transistor and the gate electrode.

A gate signal with respect to the gate electrode may be applied to the gate electrode, the gate connection layer, and the second overlapped lower layer.

The second overlapped lower layer may be covered by the active layer and the interlayer conductive layer.

The light emitting element may include a first electrode, a second electrode, and a light emitting layer electrically connected between the first electrode and the second electrode. The gate electrode, a gate connection layer, and the second overlapped lower layer may be closer to the first electrode than the second electrode, and may be covered by the first electrode.

The first electrode may be an anode electrode with respect to the light emitting layer, and the second electrode may be a cathode electrode with respect to the light emitting layer.

The pixel circuit layer may include a first power line supplying a first power source; and a second power line supplying a second power source different from the first power source. The first power line may be electrically connected to the driving transistor, and the second power line may be electrically connected to the second electrode.

The light emitting element may be an organic light emitting diode.

A display device may include a pixel circuit including a driving transistor; a switching transistor; and a storage capacitor; and a light emitting element electrically connected to the pixel circuit, the light emitting element including an anode electrode; a light emitting layer; and a cathode electrode, wherein the storage capacitor includes an upper electrode and a lower electrode, a gate electrode of the driving transistor is electrically connected to the switching transistor, the pixel circuit includes an overlapped lower layer disposed with the lower electrode in a same layer, the overlapped lower layer overlapping the gate electrode in a plan view, and the gate electrode is electrically connected to the lower electrode, and is not electrically connected to the overlapped lower layer.

A display device may include a pixel circuit including a driving transistor; and a switching transistor; and a light emitting element electrically connected to the pixel circuit, the light emitting element including an anode electrode; a light emitting layer; and a cathode electrode, wherein a first gate electrode of the driving transistor is electrically connected to the switching transistor to be applied with a gate signal, the pixel circuit includes at least two electrode patterns to which the gate signal is applied, and the at least two electrode patterns overlap the anode electrode in a plan view.

### BRIEF DESCRIPTION OF THE DRAWINGS

The above and other aspects and features of the disclosure will become more apparent by describing in detail embodiments thereof with reference to the attached drawings, in which:

FIG. 1 is a block diagram illustrating a display device in accordance with an embodiment.

FIG. 2 is a schematic cross-sectional view illustrating a display device in accordance with an embodiment.

FIG. 3 is a schematic diagram of an equivalent circuit of a pixel included in a sub-pixel in accordance with an embodiment.

FIG. 4 is a schematic cross-sectional view illustrating a stacked structure of a display device in accordance with an embodiment.

FIGS. 5 and 6 are schematic plan views illustrating an electrode structure in accordance with an embodiment.

FIG. 7 is a schematic plan view illustrating a pixel circuit in accordance with an embodiment.

FIG. 8 is a schematic plan view illustrating a connection structure between electrodes.

FIG. 9 is a schematic cross-sectional view taken along line A-A′ shown in FIG. 5.

FIG. 10 is a schematic cross-sectional view taken along line B-B′ shown in FIG. 5.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Further, an expression that an element such as a layer, region, substrate or plate is placed “on” or “above” another element indicates not only a case where the element is placed “directly on” or “just above” the other element but also a case where a further element or elements is/are interposed between the element and the other element/elements. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The disclosure generally relates to a display device. Hereinafter, a display device in accordance with an embodiment will be described with reference to the accompanying drawings.

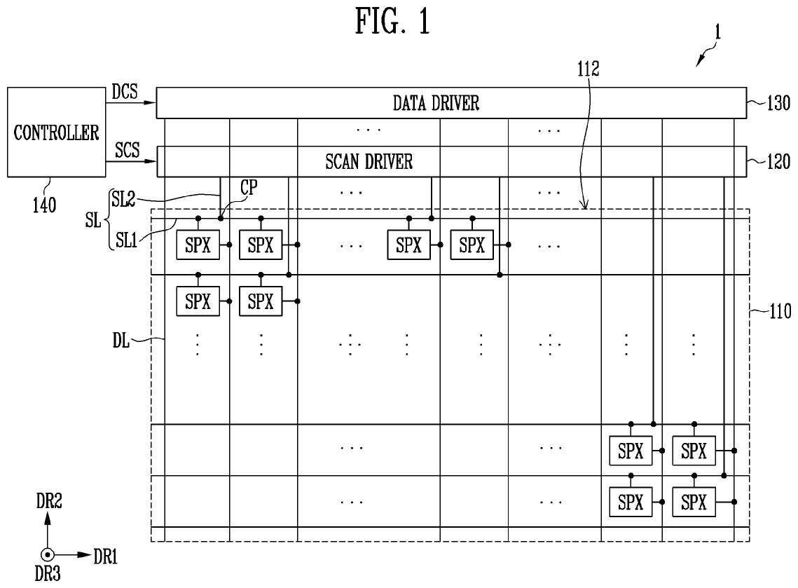

A display device 1 in accordance with an embodiment will be described with reference to FIG. 1. FIG. 1 is a block diagram illustrating a display device in accordance with an embodiment.

The display device 1 emits light. The display device 1 may be an electronic device using the light emitting element LD as a light source. In an embodiment, the display device 1 may include a pixel unit 110, a scan driver 120, a data driver 130, and a controller 140.

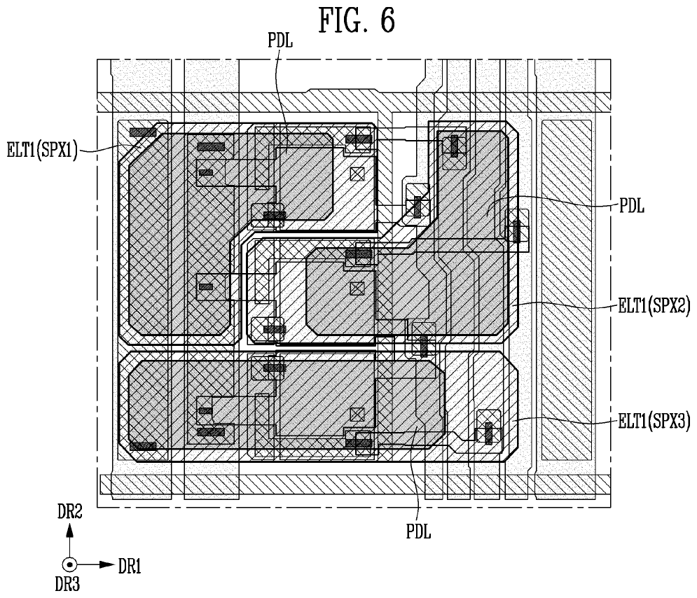

The pixel unit 110 may include sub-pixels SPX connected to scan lines SL and data lines DL. In an embodiment, at least one of the sub-pixels SPX may form (or constitute a pixel (or a pixel unit). For example, the sub-pixel SPX may include a first sub-pixel SPX1 (see FIG. 6) emitting light of a first color (for example, red), a second sub-pixel SPX2 (see FIG. 6) emitting light of a second color (for example, green), and a third sub-pixel SPX3 (see FIG. 6) emitting light of a third color (for example, blue). However, the disclosure is not limited to the above-described example.

The scan driver 120 may be disposed at one side or a side 112 of the pixel unit 110. The scan driver 120 may receive a first control signal SCS from the controller 140. The scan driver 120 may provide a scan signal to the sub-pixel SPX. The scan driver 120 may supply the scan signal to the scan lines SL in response to the first control signal SCS. For example, the scan signal may be provided to the sub-pixel SPX through a first scan line SL1 extending in a first direction DR1 and a second scan line SL2 extending in a second direction DR2.

The first control signal SCS may be a signal for controlling a driving timing of the scan driver 120. The first control signal SCS may include a scan start signal for the scan signal and clock signals. The scan signal may be set to a gate-on level corresponding to the type of a transistor to which the corresponding scan signal is supplied.

The data driver 130 may be disposed at the one side or a side 112 of the pixel unit 110. The data driver 130 may receive a second control signal DCS from the controller 140. The data driver 130 may provide a data signal to the sub-pixel SPX. The data driver 130 may supply the data signal to the data line DL in response to the second control signal DCS. For example, the second control signal DCS may be provided to the sub-pixel SPX through the data line DL. The second control signal DCS may be a signal for controlling a driving timing of the data driver 130.

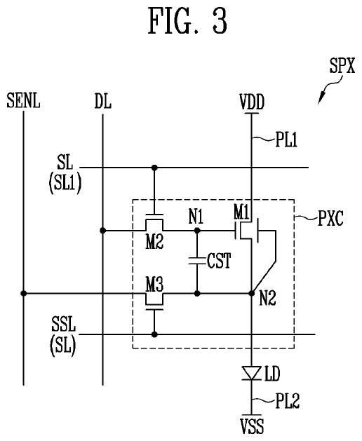

In accordance with an embodiment, the display device 1 may further include a compensator (not shown). The compensator may receive a third control signal for sensing of the sub-pixels SPX and degradation compensation from the controller 140. The compensator may receive a sensing value (current or voltage information) extracted from the sub-pixel SPX through a sensing line (‘SENL’ shown in FIG. 3). The compensator may generate a compensation value for compensating for degradation of the sub-pixel SPX, based on the sensing value.

A single side driving structure may be provided, in which the scan driver 120 and the data driver 130 are disposed at the one side or a side 112 of the pixel unit 110. The scan driver 120 and the data driver 130 may be disposed at a same side with respect to the pixel unit 110. For example, in case that the display device 1 generally includes four sides, the scan driver 120 and the data driver 130 may be disposed adjacent to a same side as any one of the four sides.

In accordance with an embodiment, in order to form the single side driving structure of the display device 1, the scan line SL may include the first scan line SL1 and the second scan line SL2, which extend in different directions.

The first scan line SL1 may extend in the first direction, to be electrically connected to sub-pixels SPX of a pixel row corresponding thereto. The second scan line SL2 may extend in the second direction DR2, to be electrically connected to the first scan line SL1 at a contact area CP. A scan signal supplied through the second scan line SL2 may be supplied to the sub-pixels SPX through the first scan line SL1.

The first scan line SL1 may be connected to at least one second scan line SL2. For example, referring to a pixel row illustrated at a top side of the pixel unit 110 shown in FIG. 1, the first scan line SL1 may be electrically connected to any one of the second scan lines SL2 in one area or an area, and be electrically connected to another of the second scan lines SL2 in another area.

The data line DL may extend along a pixel column (for example, the second direction DR2), to be electrically connected to a sub-pixel SPX. The data line DL may supply a data signal to the sub-pixel SPX connected thereto.

A pixel row direction is a horizontal direction, and may mean the first direction DR1. A pixel column direction is a vertical direction, and may mean the second direction DR2. The pixel row may be defined by the second scan line SL2. The pixel row direction may be equal (or substantially parallel) to a direction in which the one side or a side 112 of the pixel unit 110, at which the scan driver 120 and the data driver 130 are disposed, extends.

Although a case where the scan driver 120, the data driver 130, and the controller 140 are distinguished from one another is illustrated in FIG. 1, at least some of the scan driver 120, the data driver 130, and the controller 140 may be integrated into one module or one integrated circuit chip (IC chip).

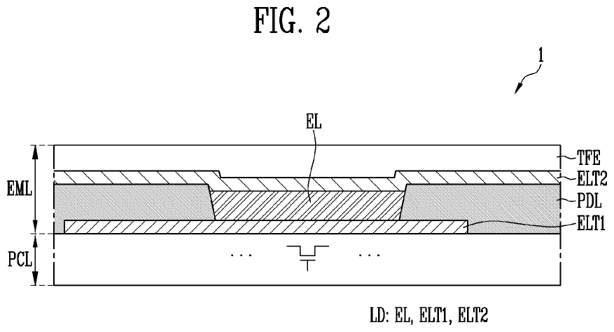

A stacked structure including a light emitting element LD for forming a sub-pixel in accordance with an embodiment will be described with reference to FIG. 2. FIG. 2 is a schematic cross-sectional view illustrating a display device in accordance with an embodiment.

In accordance with an embodiment, the display device 1 (or the sub-pixel SPX) may include light emitting elements LD. In an embodiment, the light emitting elements LD may be provided in various forms. In this specification, for convenience of description, an embodiment in which each of the light emitting element LD is an organic light emitting diode (OLED) will be described.

Referring to FIG. 2, the display device 1 may include a pixel circuit layer PCL and a light emitting element layer EML.

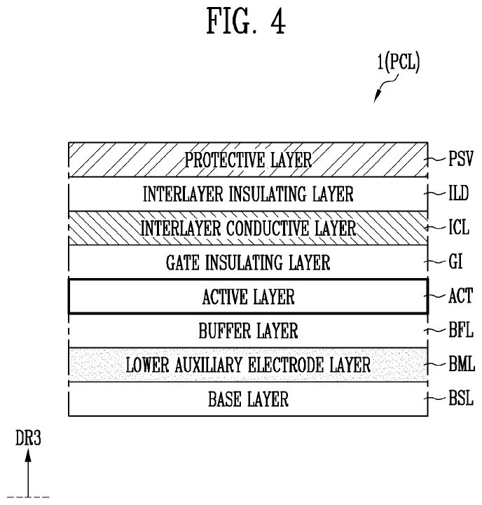

The pixel circuit layer PCL may be a layer including a pixel circuit PXC (see FIG. 3) for driving the light emitting element LD. The pixel circuit layer PCL may include a base layer BSL (see FIG. 4), conductive layers for forming pixel circuits, and insulating layers disposed between the conductive layers. A stacked structure for forming the pixel circuit layer PCL will be described in detail with reference to drawings after FIG. 4.

In accordance with an embodiment, the base layer BSL may be a base substrate or a base member, which is used to support the display device 1. The base layer BSL may be a rigid substrate made of glass. As an example, the base layer BSL may be a flexible substrate which is bendable, foldable, rollable, and the like within the spirit and the scope of the disclosure. The base layer BSL may include an insulating material including a polymer resin and the like, such as polyimide.

In accordance with an embodiment, the pixel circuit PXC may include a thin film transistor, and be electrically connected to the light emitting element LD to provide an electrical signal for allowing the light emitting elements LD to emit light. A structure of the pixel circuit PXC will be described in detail with reference to FIG. 3.

The light emitting element layer EML may be disposed on the pixel circuit layer PCL. In an embodiment, the light emitting element layer EML may include a light emitting element LD, a pixel defining layer PDL, and a thin film encapsulation layer TFE.

The light emitting element LD may be disposed on the pixel circuit layer PCL. In an embodiment, the light emitting element LD may include a first electrode ELT1, a light emitting layer EL, and a second electrode ELT2. In an embodiment, the light emitting layer EL may be disposed in an area defined by the pixel defining layer PDL. One surface or a surface of the light emitting layer EL may be electrically connected to the first electrode ELT1, and the other surface of the light emitting element EL may be electrically connected to the second electrode ELT2.

The first electrode ELT1 may be an anode electrode with respect to the light emitting layer EL, and the second electrode ELT2 may be a common electrode (or cathode electrode) with respect to the light emitting element EL. In accordance with an embodiment, the first electrode ELT1 and the second electrode ELT2 may include a conductive material. For example, the first electrode ELT1 may include a conductive material having reflexibility, and the second electrode ELT2 may include a transparent conductive material. However, the disclosure is not necessarily limited thereto.

The light emitting layer EL may have a multi-layer thin film structure including a light generation layer. The light emitting layer EL may include a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. The light emitting layer EL may release light, based on an electrical signal provided from the first electrode ELT1 and the second electrode ELT2.

The pixel defining layer PDL may be disposed on the pixel circuit layer PCL, to define a position at which the light emitting layer EL is arranged or disposed. The pixel defining layer PDL may include an organic material. In an embodiment, the pixel defining layer PDL may include at least one of the group consisting of acrylic resin, epoxy resin, a phenolic resin, polyamide resin, and polyimide resin. However, the disclosure is not limited thereto.

The thin film encapsulation layer TFE may be disposed on the light emitting element LD (for example, the second electrode ELT2). The thin film encapsulation layer TFE may cancel a step difference generated by the light emitting element LD and the pixel defining layer PDL. The thin film encapsulation layer TFE may include insulating layers covering the light emitting element LD. In an embodiment, the thin film encapsulation layer TFE may have a structure in which an inorganic layer and an organic layer may be alternately stacked each other.

A pixel circuit PXC in accordance with an embodiment will be described with reference to FIG. 3. FIG. 3 is a schematic diagram of an equivalent circuit of a pixel included in a sub-pixel in accordance with an embodiment.

Referring to FIG. 3, the sub-pixel SPX may include a pixel circuit PXC. The pixel circuit PXC drives light emitting elements LD. In an embodiment, each of sub-pixels SPX for forming one pixel unit may include the pixel circuit PXC.

The sub-pixel SPX may be electrically connected to a scan lines SL, a data line DL, a first power line PL1, and a second power line PL2. The sub-pixel SPX may be further electrically connected to a sensing line SENL. In FIG. 3, the scan line SL may mean the above-described first scan line SL1. For convenience of description, the first scan line SL1 is designated and described as the scan line SL.

The sub-pixel SPX may include light emitting elements LD that emit light corresponding to a data signal provided from the data line DL.

The pixel circuit PXC may be disposed between the first power line PL1 and the light emitting elements LD. The pixel circuit PXC may be electrically connected to the scan line SL to which a first scan signal is supplied and the data line DL to which a data signal is supplied. The pixel circuit PXC may be electrically connected to a control line SSL to which a second scan signal is supplied, and be electrically connected to the sensing line SENL connected to a reference power source (or initialization power source) or a sensing circuit. In an embodiment, the second scan signal may be equal to or different from the first scan signal. In case that the second scan signal is equal to the first scan signal, the control line SSL may be integrated with the scan line SL.

The pixel circuit PXC may include at least one circuit element. For example, the pixel circuit PXC may include a first transistor M1, a second transistor M2, a third transistor M3, and a capacitor CST.

The first transistor M1 may be electrically connected between the first power line PL1 and a second node N2. The second node N2 may be a node at which the pixel circuit PXC and the light emitting element LD are connected to each other. For example, the second node N2 may be a node at which one electrode (for example, a drain electrode) of the first transistor M1 and a first electrode ELT1 of the light emitting element LD are connected to each other. A gate electrode of the first transistor M1 may be electrically connected to a first node N1. The first transistor M1 may control a driving current supplied to the light emitting element LD, corresponding to a voltage of the first node N1. The first transistor M1 may be a driving transistor.

In an embodiment, an electrode layer electrically connected to the second node N2 such that an anode signal supplied to the light emitting element LD is applied thereto may be disposed under or below the first transistor M1 (for example, the gate electrode of the first transistor M1).

The second transistor M2 may be electrically connected between the data line DL and the first node N1. A gate electrode of the second transistor M2 may be electrically connected to the scan line SL. The second transistor M2 may be turned on in case that the first scan signal having a gate-on voltage (for example, a high level voltage) is supplied from the scan line SL, to electrically connect the data line DL and the first node N1 to each other.

A data signal of a corresponding frame is supplied to the data line for each frame period. The data signal is transferred to the first node N1 through the second transistor M2 during a period in which the first scan signal having the gate-on voltage is supplied. For example, the second transistor M2 may be a switching transistor for transferring each data signal to the inside of the sub-pixel SPX.

One electrode of the storage capacitor CST may be electrically connected to the first node N1, and the other electrode of the storage capacitor CST may be electrically connected to the second node N2. The storage capacitor CST charges a voltage corresponding to the data signal supplied to the first node N1 during each frame period.

The third transistor M3 may be electrically connected between the second node N2 and the sensing line SENL. A gate electrode of the third transistor M3 may be connected to the control line SSL (or the scan line SL). The third transistor M3 may be turned on in case that the second scan signal (or the first scan signal) having the gate-on voltage (for example, the high level voltage) is supplied from the control line SSL, to transfer, to the second node N2, a reference voltage (or initialization voltage) supplied to the sensing line SENL, or to transfer a voltage of the second node N2 to the sensing line SENL. The voltage of the second node N2, which is transferred to the sensing circuit through the sensing line SENL, may be provided to an external circuit (for example, the controller 140) to be used for compensating for a characteristic deviation of sub-pixels SPX, and the like within the spirit and the scope of the disclosure.

Although a case where the transistors included in the pixel circuit PXC are all N-type transistors is illustrated in FIG. 3 the disclosure is not limited thereto. For example, at least one of the first, second, and third transistors M1, M2, and M3 may be changed to a P-type transistor. The structure and driving method of the sub-pixel SPX may be variously changed in an embodiment.

The light emitting element LD may be electrically connected between the first power line PL1 and the second power line PL2. For example, the first electrode ELT1 of the light emitting element LD may be electrically connected to the pixel circuit PXC, and a second electrode ELT2 of the light emitting element LD may be electrically connected to the second power line PL2.

A power source of the first power line PL1 and a power source of the second power line PL2 may have different potentials. For example, the power source of the first power line PL1 may be a high-potential pixel power source which is supplied with a power source from a first power source VDD, and the power source of the second power line PL2 may be a low-potential pixel power source which is supplied with a power source from a second power source VSS. A potential difference between the power source of the first power line PL1 and the power source of the second power line PL2 may be set equal to or higher than a threshold voltage of the light emitting elements LD.

The first power line PL1 may be electrically connected to the first transistor M1. The second power line PL2 may be electrically connected to a cathode electrode (for example, the second electrode ELT2) of the light emitting element LD.

The emitting elements LD may be connected in a forward direction between the first power line PL1 and the second power line PL2 to form respective effective light sources. These effective light sources constitute the light emitting elements LD of the sub-pixel SPX.

The light emitting elements LD may emit light with a luminance corresponding to a driving current supplied through the pixel circuit PXC. The pixel circuit PXC may supply a driving current corresponding to a data signal to the light emitting element LD during each frame period. The light emitting element LD emits light with a luminance corresponding to a current flowing therethrough.

The pixel circuit PXC of the sub-pixel SPX in accordance with an embodiment is not limited to the above-described example. In an embodiment, the pixel circuit PXC may further include seven transistors and one storage capacitor.

A structure of electrodes of the display device 1 in accordance with an embodiment will be described with reference to FIGS. 4 to 10. In FIGS. 4 to 10, descriptions of portions overlapping the above-described portion will be simplified or may not be repeated.

FIG. 4 is a schematic cross-sectional view illustrating a stacked structure of a display device in accordance with an embodiment.

Referring to FIG. 4, the stacked structure included in the display device 1 (for example, the pixel circuit layer PCL) may have a form in which at least a portion of a structure is patterned, in which a base layer BSL, a lower auxiliary electrode layer BML, a buffer layer BFL, an active layer ACT, a gate insulating layer GI, an interlayer conductive layer ICL, an interlayer insulating layer ILD, and a protective layer PSV may be sequentially stacked each other. For example, the above-described electrode layers may be patterned according to one structure, to form a pixel circuit PXC.

The base layer BSL may form (or constitute) a base surface of the display device 1. As described above, the base layer BSL may include various materials, and its example is not particularly limited.

The buffer layer BFL may be a layer for preventing an impurity from being diffused into the active layer ACT including a semiconductor or preventing moisture from infiltrating into the active layer ACT. In an embodiment, the buffer layer BFL may include at least one selected from the group consisting of silicon nitride (SiNₓ), silicon oxide (SiOₓ), silicon oxynitride (SiOₓN_{y}), and aluminum oxide (AlOₓ). However, the disclosure is not necessarily limited to the above-described example.

The active layer ACT may include a semiconductor. For example, the active layer ACT may include at least one selected from the group consisting of poly-silicon, Low Temperature Polycrystalline Silicon (LTPS), amorphous silicon, and an oxide semiconductor. In an embodiment, the active layer ACT may form a channel of the first transistor M1, the second transistor M2, and the third transistor M3, and an impurity may be doped into, as a portion of the interlayer conductive layer ICL, a portion in contact with a source electrode or a drain electrode of each of the first transistor M1, the second transistor M2, and the third transistor M3.

The lower auxiliary electrode layer BML and the interlayer conductive layer ICL may include a conductive material. In accordance with an embodiment, each of the lower auxiliary electrode layer BML and the interlayer conductive layer ICL may include at least one conductive layer. In an embodiment, each of the lower auxiliary electrode layer BML and the interlayer conductive layer ICL may include at least one selected from the group consisting of gold (Au), silver (Ag), aluminum (Al), molybdenum (Mo), chromium (Cr), titanium (Ti), nickel (Ni), neodymium (Nd), copper (Cu), and platinum (Pt). However, the disclosure is not necessarily limited to the above-described example.

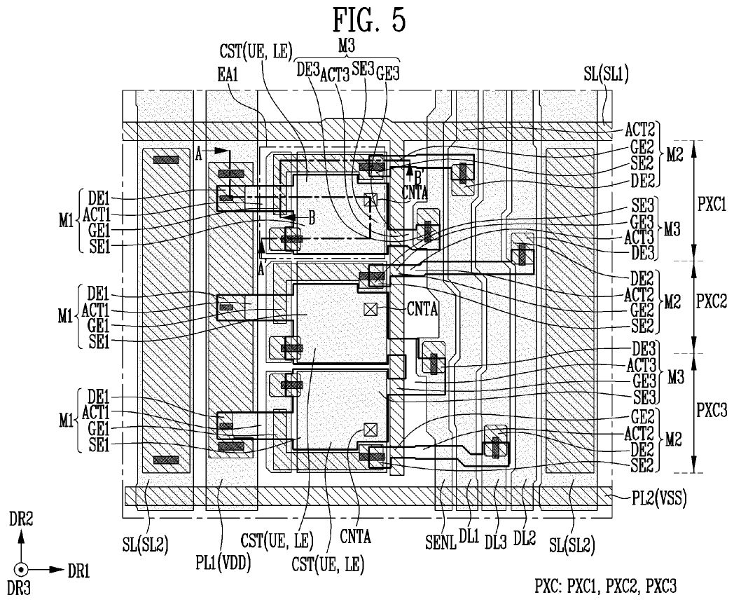

The gate insulating layer GI, the interlayer insulating layer ILD, and the protective layer PSV may be disposed between the active layer ACT and the interlayer conductive layer ICL to electrically separate the active layer ACT and the interlayer conductive layer ICL from each other. In accordance with an embodiment, the active layer ACT and the interlayer conductive layer ICL may be electrically connected to each other through contact parts (for example, an anode contact part CNTA (see FIG. 5) or contact holes, which are formed in at least one of the gate insulating layer GI, the interlayer insulating layer ILD, and the protective layer PSV.

In accordance with an embodiment, the gate insulating layer GI, the interlayer insulating layer ILD, and/or the protective layer PSV may include at least one selected from the group consisting of silicon nitride (SiNₓ), silicon oxide (SiOₓ), silicon oxynitride (SiOₓN_{y}), and aluminum oxide (AlOₓ). However, the disclosure is not necessarily limited to the above-described example. In an embodiment, gate insulating layer GI, the interlayer insulating layer ILD, and/or the protective layer PSV may include an organic material.

A planar structure of electrodes for forming the pixel circuit layer PCL will be described with reference to FIGS. 5 and 6. In the following drawings, the same layers as the above-described layers (for example, patterning in a same process) may be expressed by using a same hatching.

FIGS. 5 and 6 are schematic plan views illustrating an electrode structure in accordance with an embodiment. In FIG. 5, the lower auxiliary electrode layer BML, the active layer ACT, and the interlayer conductive layer ICL are illustrated. In order to clearly describe positions of the first electrode ELT1 of the light emitting element LD and the pixel defining layer PDL, FIG. 6 illustrates images of the lower auxiliary electrode layer BML, the active layer ACT, and the interlayer conductive layer ICL, but illustration of reference numerals representing the respective layers is omitted. The position of each component will be clearly understood with reference to FIGS. 5 and 6 together.

In FIGS. 5 and 6, an anode contact part CNTA is illustrated to have a form in which an X is displayed in a quadrangular shape or a substantially quadrangular shape. In FIGS. 5 and 6, contact holes for electrically connecting different patterns (for example, the lower auxiliary electrode layer BML, the active layer ACT, and the interlayer conductive layer ICL) to each other are illustrated in a quadrangular shape or a substantially quadrangular shape expressed by using a darker hatching.

In accordance with an embodiment, pixel circuits PXC and lines connected to the pixel circuits PXC may be disposed (or patterned).

For example, the pixel circuit PXC may include a first pixel circuit PXC1, a second pixel circuit PXC2, and a third pixel circuit PXC3. Each of the first pixel circuit PXC1, the second pixel circuit PXC2, and the third pixel circuit PXC3 may include a first transistor M1, a second transistor M2, a third transistor M3, and a storage capacitor CST. The first pixel circuit PXC1, the second pixel circuit PXC2, and the third pixel circuit PXC3 may be spaced apart from each other along the second direction DR2. Each of the first pixel circuit PXC1, the second pixel circuit PXC2, and the third pixel circuit PXC3 may be a pixel circuit PXC with respect to each of different sub-pixels SPX.

In accordance with an embodiment, the first transistor M1 of each of the first pixel circuit PXC1, the second pixel circuit PXC2, and the third pixel circuit PXC3 may include a first source electrode SE1, a first gate electrode GE1, a first drain electrode DE1, and a first active layer ACT1. In accordance with an embodiment, the second transistor M2 of each of the first pixel circuit PXC1, the second pixel circuit PXC2, and the third pixel circuit PXC3 may include a second source electrode SE2, a second gate electrode GE2, a second drain electrode DE2, and a second active layer ACT2. In accordance with an embodiment, the third transistor M3 of each of the first pixel circuit PXC1, the second pixel circuit PXC2, and the third pixel circuit PXC3 may include a third source electrode SE3, a third gate electrode GE3, a third drain electrode DE3, and a third active layer ACT3.

The storage capacitor CST may include an upper electrode UE and a lower electrode LE. In an embodiment, the upper electrode UE may be formed by the active layer ACT, and the lower electrode LE may be formed by the lower auxiliary electrode layer BML. However, the disclosure is not necessarily limited to the above-described example. In an embodiment, the upper electrode UE may be formed by at least one (for example, the interlayer conductive layer ICL, and the like) among layers disposed upward of the lower auxiliary electrode layer BML.

A first scan line SL1 among scan lines SL may extend in the first direction DR1. A second scan line SL2 among the scan lines SL may extend in the second direction DR2. The first scan line SL1 and the second scan line SL2 may be electrically connected to each other through a contact area CP (not shown in these drawings). The first scan line SL1 and the second scan line SL2 may be formed by one conductive layer(s). For example, the first scan line SL1 may include the interlayer conductive layer ICL. The second scan line SL2 may include the lower auxiliary conductive layer BML and the interlayer conductive layer ICL.

Data lines DL may extend in the second direction DR2. The data lines DL may be spaced apart from each other in the first direction DR1. The data lines DL may include a first data line DL1, a second data line DL2, and a third data line DL3. The first data line DL1 is a data line with respect to the first pixel circuit PXC1, and may be electrically connected to a second drain electrode DE2 of a second transistor M2 of the first pixel circuit PXC1. The second data line DL2 is a data line with respect to the second pixel circuit PXC2, and may be electrically connected to a second drain electrode DE2 of a second transistor M2 of the second pixel circuit PXC2. The third data line DL3 is a data line with respect to the third pixel circuit PXC3, and may be electrically connected to a second drain electrode DE2 of a second transistor M2 of the third pixel circuit PXC3.

A sensing line SENL may extend in the second direction DR2. The sensing line SENL may be electrically connected to the third drain electrode DE3 of the third transistor M3 of each of the first to third pixel circuits PXC1, PXC2, and PXC3.

A first power line PL1 supplied with a power source from a first power source VDD may extend in the second direction DR2, and be electrically connected to the first drain electrode DE1 of the first transistor M1 of each of the first to third pixel circuits PXC1, PXC2, and PXC3.

A second power line PL2 supplied with a power source from a second power source VSS may extend in the first direction DR1. Although not shown in the drawings, the second power line PL2 may be electrically connected to a second electrode ELT2 entirely disposed in an area in which a sub-pixel SPX through one cathode contact part.

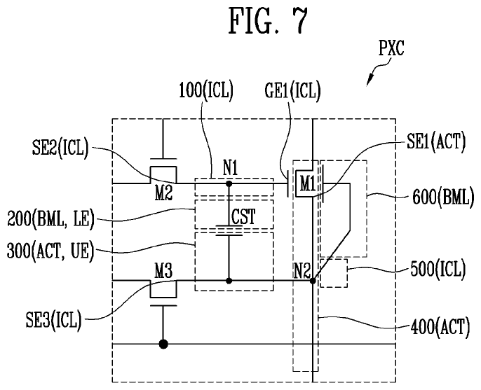

In accordance with an embodiment, an anode contact part CNTA electrically connected to the first source electrode SE1 of the first transistor M1 may be connected to a portion of the active layer ACT. For example, an anode signal supply layer 400 (see FIG. 7) may be electrically connected to the first source electrode SE1 of the first transistor M1, and simultaneously, be electrically connected to an anode contact part CNTA connected to a first electrode ELT1.

At least a portion of an electrical path through which a gate signal supplied to the first gate electrode GE1 of the first transistor M1 is moved may be formed in the lower auxiliary electrode layer BML. A conduction path through which a gate signal is applied to the first transistor M1 as a driving transistor may be covered by the interlayer conductive layer ICL or the active layer ACT. Experimentally, in case that the conduction path through which the gate signal is applied is directly adjacent to the first electrode ELT1, there exists a risk that a coupling capacitance between both electrodes will be formed. Experimentally, in case that the coupling capacitance is generated, there exists a concern that an electrical signal supplied to the sub-pixel SPX will be distorted, and a horizontal crosstalk phenomenon and a color deviation phenomenon may be caused due to a signal delay. However, in accordance with an embodiment, a portion of an electrode layer in which the gate signal is supplied to the first transistor M1 is formed in the lower auxiliary electrode layer BML, so that formation of the coupling capacitance can be prevented. Thus, the reliability of an electric signal can be improved, and the horizontal crosstalk phenomenon and the color deviation phenomenon can be prevented.

The first electrode ELT1 may be an anode electrode of each of first to third sub-pixels SPX1, SPX2, and SPX3. Accordingly, first electrodes ELT1 of the respective first to third sub-pixels SPX1, SPX2, and SPX3 may be spaced apart from each other to be supplied with anode signals from the respective first to third pixel circuits PXC1, PXC2, and PXC3.

In accordance with an embodiment, the first electrode ELT1 may be electrically connected to a portion of the active layer ACT through the anode contact part CNTA, and be electrically connected to the first source electrode SE1 of the first transistor M1. Accordingly, the first electrode ELT1 is applied with a driving signal. In accordance with an embodiment, the anode signal is not applied to a layer different from the first source electrode but may be applied directly to the first electrode ELT1 as an anode electrode of the light emitting element LD. Thus, any additional electrode pattern is not required, and accordingly, process cost can be reduced.

A pixel defining layer PDL may be selectively patterned in a partial area such that a light emitting layer EL of a light emitting element LD. Therefore, at least the pixel defining layer PDL may not be disposed on a partial area of the first electrode ELT1, and accordingly, an area in which the light emitting layer EL is disposed may be defined.

In accordance with an embodiment, the first electrode ELT1 may cover the electrical path through which the gate signal supplied to the first gate electrode GE1 of the first transistor M1 is moved. For example, the electrical path through which the gate signal supplied to the first gate electrode GE1 is moved may entirely overlap the first electrode ELT1 in a plan view. The gate signal supplied to the first gate electrode GE1 is coupled or connected to a common potential formed in the second electrode ELT2, so that the risk that the gate signal will be distorted can be prevented.

A connection structure between electrodes in accordance with an embodiment will be described with reference to FIGS. 7 to 10. In FIGS. 7 to 10, descriptions of portions overlapping the above-described portion will be simplified or may not be repeated.

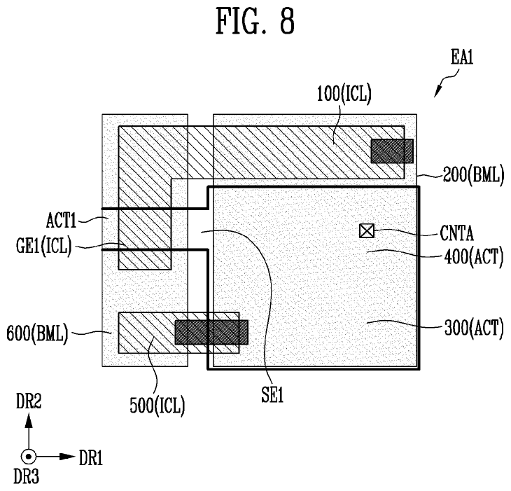

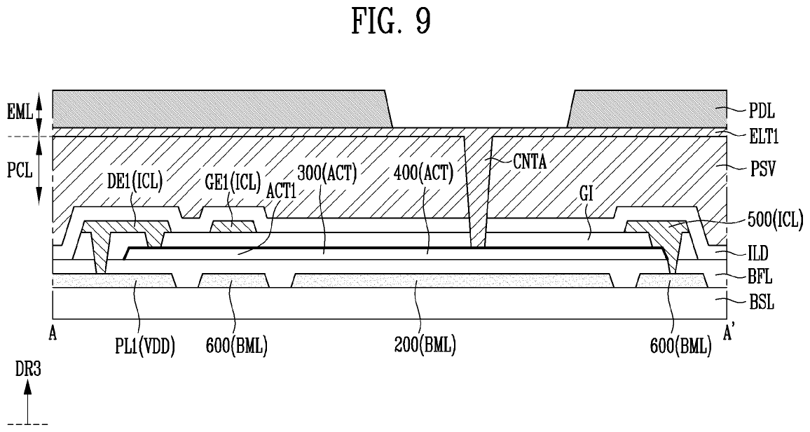

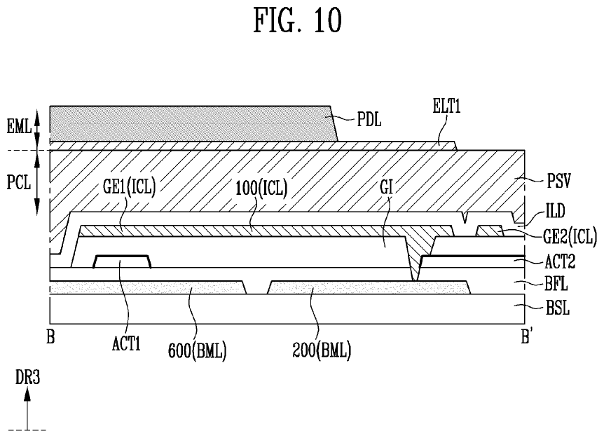

FIG. 7 is a schematic plan view illustrating a pixel circuit in accordance with an embodiment. FIG. 8 is a schematic plan view illustrating a connection structure between electrodes. More specifically, FIG. 8 is a schematic enlarged view of region EA1 of FIG. 5 illustrating a connection structure between electrodes in a more intuitive manner. FIG. 9 is a schematic cross-sectional view taken along line A-A′ shown in FIG. 5. FIG. 10 is a schematic cross-sectional view taken along line B-B′ shown in FIG. 5.

Referring to FIGS. 7 to 10, electrode patterns form a connection structure of the pixel circuit PXC, and form an electrical path through which an electrical signal is applied.

The first gate electrode GE1 of the first transistor M1 may be formed by the interlayer conductive layer ICL. The first gate electrode GE1 may overlap the first active layer ACT1, be disposed in a same layer as a gate connection layer 100, and be electrically connected to the second source electrode SE2 of the second transistor M2 through the gate connection layer 100. In an embodiment, the first gate electrode GE1 may be electrically connected to a second overlapped lower layer 200 formed in the lower auxiliary electrode layer BML through the gate connection layer 100. In an embodiment, at least a portion of the second overlapped lower layer 200 may form the lower electrode LE of the storage capacitor CST.

The gate connection layer 100 is a layer formed in the interlayer conductive layer ICL, and may be electrically connected to the second source electrode SE2. A portion of the gate connection layer 100 may be electrically connected to the first gate electrode GE1, and another portion of the gate connection layer 100 may be electrically connected to the second overlapped lower layer 200 through one contact hole.

The second overlapped lower layer 200 is a formed in the lower auxiliary electrode layer BML, and may be electrically connected to the gate connection layer 100 through one contact hole. The second overlapped lower layer 200 may form the lower electrode LE of the storage capacitor CST.

A gate signal to be supplied to the first transistor M1 may be supplied (or applied) to the gate connection layer 100, the second overlapped lower layer 200, and the first gate electrode GE1.

In accordance with an embodiment, the second overlapped lower layer 200 may overlap the gate connection layer 100, an active connection layer 300, and the anode signal supply layer 400 in a plan view. Thus, a risk that the second overlapped lower layer 200 will be coupled or connected to the second electrode ELT2 serving as a common electrode of the sub-pixel SPX can be prevented.

In accordance with an embodiment, the second overlapped lower layer 200 may be electrically separated or disconnected from a first overlapped lower layer 600. For example, the second overlapped lower layer 200 may be patterned with the first overlapped lower layer 600 in a same layer, and be physically spaced apart from each other. Accordingly, as electrodes patterned in a same layer, a gate signal with respect to the driving transistor may be applied to a portion of the lower auxiliary electrode layer BML, and an anode signal with respect to the light emitting element LD may be applied to another portion of the lower auxiliary electrode layer BML.

In accordance with an embodiment, a structure may be provided in which one electrode (for example, the lower electrode LE) of the storage capacitor CST, to which the gate signal with respect to the driving transistor is supplied, is formed in the lower auxiliary electrode layer BML. As described above, since the electrode patterns to which the gate signal is supplied are patterned under or below the electrodes to be covered by the electrodes, a risk caused by coupling with the second electrode ELT2 serving as the common electrode.

The active connection layer 300 is a layer formed in the active layer ACT, and may be electrically connected to the first active layer ACT1, the anode signal supply layer 400, an anode connection layer 500, and the first overlapped lower layer 600. In accordance with an embodiment, the active connection layer 300 may be electrically connected to the third source electrode SE3 of the third transistor M3. The active connection layer 300 may form the upper electrode UE.

In accordance with an embodiment, the active connection layer 300 may be integrally formed or integral with the anode signal supply part 400. For example, a portion of the active layer ACT on an area overlapping the second overlapped lower layer 200 in a plan view may be defined as the active connection layer 300, and a portion of the active layer ACT on the area may be defined as the anode signal supply layer 400.

In accordance with an embodiment, the active connection layer 300 may be disposed more adjacent to the second electrode ELT2 than the second overlapped lower layer 200. Accordingly, the active connection layer 300 covers the second overlapped lower layer 200, thereby improving the reliability of the gate signal with respect to the driving transistor.

In accordance with an embodiment, the active connection layer 300 and the second overlapped lower layer 200 may respectively form surfaces facing each other. Accordingly, the active connection layer 300 and the second overlapped lower layer 200 can form a storage capacitor CST structure.

In accordance with an embodiment, the active connection layer 300 may be electrically connected to the first overlapped lower layer 600 formed in the lower auxiliary electrode layer BML through the anode signal supply layer 400 and the anode connection layer 500.

The anode signal supply layer 400 is a layer formed in the active layer ACT, and may be electrically connected to the active connection layer 300, the anode connection layer 500, and the first overlapped lower layer 600. The anode signal supply layer 400 may include the first source electrode SE1 of the first transistor M1. In an embodiment, an anode signal supplied to the anode signal supply layer 400 may be applied to the active connection layer 300, the anode connection layer 500, and the first overlapped lower layer 600.

The anode signal supply layer 400 may be integrally formed or integral with the active connection layer 300, to include a partial area of the upper electrode UE. In an embodiment, the anode signal supply layer 400 may be electrically connected to the first electrode ELT1 through an anode contact part CNTA. An anode signal supplied by the first transistor M1 may be directly applied to the first electrode ELT1 through the active layer ACT.

The anode connection layer 500 is a layer formed in the interlayer conductive layer ICL, and may electrically connect the anode signal supply layer 400 (or the active connection layer 300) and the first overlapped lower layer 600 to each other. Accordingly, an anode signal to be supplied to the light emitting element LD may be applied to the first overlapped lower layer 600 located or disposed under or below the first gate electrode GE1.

The first overlapped lower layer 600 is a layer formed in the lower auxiliary electrode layer BML, and may be applied with the anode signal to be supplied to the light emitting element LD through the anode connection layer 500. As described above, the anode signal may be a driving signal provided from the first source electrode SE1 of the first transistor M1.

The first overlapped lower layer 600 may be disposed under or below the first active layer ACT1. For example, in a plan view, the first overlapped lower layer 600 may overlap an area in which the first gate electrode GE1 and the first active layer ACT1 overlap each other. In case that an anode signal is applied to light emitting elements LD, the anode signal may be simultaneously applied to electrode layers respectively disposed above or under or below the first active layer ACT1 with respect to the first active layer ACT1. Thus, a turn-off characteristic of the first transistor M1 can be remarkably improved. For example, an anode signal supplied to the first overlapped lower layer 600 overlapping the first transistor M1 may be adjusted, thereby moving a threshold voltage of the first transistor M1 in a negative direction or a positive direction.

The first overlapped lower layer 600 is patterned with the second overlapped lower layer 200 in a same layer, and may be electrically separated or disconnected from each other. Accordingly, the first overlapped lower layer 600 overlapping the first active layer ACT1 can be applied with the anode signal with respect to the light emitting elements LD without being applied with the gate signal with respect to the first transistor M1.

In accordance with an embodiment, at least a portion of an electrode structure to which the gate signal with respect to the first transistor M1 is applied may be formed under or below the first active layer ACT1 of the first transistor M1, and simultaneously, an electrode structure to which the anode signal is supplied may be formed under or below the first active layer ACT1 of the first transistor M1. In accordance with the embodiment, the above-described technical effects according to the respective structure can be simultaneously derived.

In accordance with an embodiment, the gate signal supplied to the first gate electrode GE1 of the first transistor M1 is applied to at least two electrode patterns, and the at least two electrode patterns may overlap the first electrode ELT1 (for example, the anode electrode) in a plan view. For example, the first gate electrode GE1, the gate connection layer 100, and the second overlapped lower layer 200 may overlap the first electrode ELT1 in a plan view. For example, the first electrode ELT1 may entirely cover the first gate electrode GE1, the gate connection layer 100, and the second overlapped lower layer 200. Thus, a risk that electrode layers to which the gate signal with respect to the first transistor M1 is applied are electrically coupled or connected to the second electrode ELT2 can be prevented.

In accordance with the disclosure, there can be provided a display device in which the reliability of an electrical signal in the display device is improved.

Example embodiments have been disclosed herein, and although terms are employed, they are used and are to be interpreted in a generic and descriptive sense only and not for purpose of limitation. In some instances, as would be apparent to one of ordinary skill in the art, features, characteristics, and/or elements described in connection with a given embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure and as set forth in the following claims.

What is claimed is:

1. A display device comprising:
a pixel circuit layer including a base layer and a pixel circuit disposed on the base layer; and
a light emitting element layer disposed on the pixel circuit layer, the light emitting element layer including a light emitting element, wherein
the pixel circuit layer includes:
a lower auxiliary electrode layer;
an active layer; and
an interlayer conductive layer,
the pixel circuit includes a driving transistor,
the lower auxiliary electrode layer forms a first overlapped lower layer and a second overlapped lower layer,
the interlayer conductive layer forms a gate electrode of the driving transistor,
the first overlapped lower layer overlaps the gate electrode in a plan view, and
the second overlapped lower layer is electrically disconnected from the first overlapped lower layer.

2. The display device of claim 1, wherein
the active layer forms an active connection layer, and
the first overlapped lower layer is electrically connected to a source electrode of the driving transistor through the active connection layer.

3. The display device of claim 2, wherein
the driving transistor supplies an anode signal to the light emitting element, and
the anode signal is simultaneously applied to the light emitting element and the first overlapped lower layer in case that the light emitting element emits light.

4. The display device of claim 3, wherein
the first overlapped lower layer is applied with the anode signal without being applied with a gate signal with respect to the driving transistor, and
the second overlapped lower layer is applied with the gate signal without being applied with the anode signal.

5. The display device of claim 4, wherein
the pixel circuit includes a storage capacitor,
the active connection layer forms an upper electrode of the storage capacitor, and
the second overlapped lower layer forms a lower electrode of the storage capacitor.

6. The display device of claim 2, wherein
the light emitting element includes:
a first electrode;
a second electrode; and
a light emitting layer electrically connected between the first electrode and the second electrode,
the active layer forms an anode signal supply layer, and
the anode signal supply layer is electrically connected to the first electrode through an anode contact part.

7. The display device of claim 6, wherein the anode signal supply layer is integral with the active connection layer.

8. The display device of claim 7, wherein the interlayer conductive layer forms an anode connection layer electrically connecting the first overlapped lower layer and the active connection layer.

9. The display device of claim 7, wherein the active connection layer is closer to the first electrode than the second overlapped lower layer.

10. The display device of claim 1, wherein
the pixel circuit includes a switching transistor, and
the interlayer conductive layer forms a gate connection layer electrically connecting the switching transistor and the gate electrode.

11. The display device of claim 10, wherein a gate signal with respect to the gate electrode is applied to the gate electrode, the gate connection layer, and the second overlapped lower layer.

12. The display device of claim 11, wherein the second overlapped lower layer is covered by the active layer and the interlayer conductive layer.

13. The display device of claim 11, wherein
the light emitting element includes a first electrode, a second electrode, and a light emitting layer electrically connected between the first electrode and the second electrode, and
the gate electrode, a gate connection layer, and the second overlapped lower layer are closer to the first electrode than the second electrode, and are covered by the first electrode.

14. The display device of claim 13, wherein
the first electrode is an anode electrode with respect to the light emitting layer, and
the second electrode is a cathode electrode with respect to the light emitting layer.

15. The display device of claim 14, wherein
the pixel circuit layer includes:
a first power line supplying a first power source; and
a second power line supplying a second power source different from the first power source,
the first power line is electrically connected to the driving transistor, and
the second power line is electrically connected to the second electrode.

16. The display device of claim 1, wherein the light emitting element is an organic light emitting diode.

17. A display device comprising:
a pixel circuit including:
a driving transistor;
a switching transistor; and
a storage capacitor; and
a light emitting element electrically connected to the pixel circuit, the light emitting element including:
an anode electrode;
a light emitting layer; and
a cathode electrode, wherein
the storage capacitor includes an upper electrode and a lower electrode,
a gate electrode of the driving transistor is electrically connected to the switching transistor,
the pixel circuit includes an overlapped lower layer disposed with the lower electrode in a same layer, the overlapped lower layer overlapping the gate electrode in a plan view, and
the gate electrode is electrically connected to the lower electrode, and is not electrically connected to the overlapped lower layer.

18. A display device comprising:
a pixel circuit including:
a driving transistor; and
a switching transistor; and
a light emitting element electrically connected to the pixel circuit, the light emitting element including:
an anode electrode;
a light emitting layer; and
a cathode electrode, wherein
a first gate electrode of the driving transistor is electrically connected to the switching transistor to be applied with a gate signal,
the pixel circuit includes at least two electrode patterns to which the gate signal is applied, and
the at least two electrode patterns overlap the anode electrode in a plan view.
